(19) United States
(12) Patent Application Publication
(10) Pub. No.: US 2025/0212702 A1
(43) Pub. Date: Jun. 26, 2025

(54) SUPERCONDUCTOR DEVICE WITH COMPOSITE MATERIAL GROUND PLANE

(71) Applicant: NORTHROP GRUMMAN SYSTEMS CORPORATION, FALLS CHURCH, VA (US)

(72) Inventors: JOHN X. PRZYBYSZ, Severna Park, MD (US); COUGAR A.T. GARCIA, Baltimore, MD (US); ERIC WILLIAM GOODWIN, Columbia, MD (US); LAURA LEONARD, Gambrills, MD (US)

(21) Appl. No.: 18/391,077

(22) Filed: Dec. 20, 2023

(51) Int. Cl. H10N 60/80; H10N 60/12; H10N 69/00

(52) U.S. Cl. CPC H10N 60/805; H10N 60/12; H10N 69/00

(57) ABSTRACT

A superconductor device disclosed includes a plurality of superconductor layers and dielectric layers interleaved with the plurality of superconductor layers with moat regions that extend through the plurality of superconductor layers and the dielectric layers and a composite material ground plane that is one of the superconductor layers of the plurality of superconductor layers, the composite ground plane comprises first regions formed of a first superconductor material, and second regions formed of a second superconductor material having a second superconducting critical temperature higher than a first superconducting critical temperature of the first superconductor material, such that at least one flux vortex caused by cryogenic cooling can be removed from the second region during cooling below the second critical temperature and above the first critical temperature to the first regions, and removed from the first regions to the moat regions upon cooling below the first critical temperature.

### GOVERNMENT INTEREST

The invention was made under Government Contract. Therefore, the US Government has rights to the invention as specified in that contract.

### TECHNICAL FIELD

The present disclosure relates to superconducting circuits, and more particularly, to a superconductor device with a composite material ground plane.

### BACKGROUND

Superconductor electronics is a unique technology that delivers fast digital circuits with extremely low power dissipation. However, superconductor electronics is still an emerging technology. As a result, there are still a variety of technical problems that remain to be solved, many of which are found in other microelectronic integrated circuit (IC) technologies. Two main groups of problems pertain to superconductor electronics. The first group of problems is associated with the necessity of cooling superconductor circuits to extremely low cryogenic temperatures. The second group of problems is associated with magnetic flux trapping. Magnetic flux trapping is affected by the background magnetic environment during the cooling and operation of superconducting ICs. It is widely accepted that magnetic flux trapping is a problem that can create an integration limit for superconductor circuits. For example, magnetic flux quanta that become trapped in non-moat regions (e.g., stray magnetic flux) are a main reason that Josephson IC chips fail to work correctly on successive cooldown cycles, as bias points of Josephson junctions can be shifted. Moat regions can sequester flux quanta in regions that are far from sensitive elements, such as the Josephson junctions.

The presence of parasitic magnetic field lines during cooling and operation severely limits the yield and performance of many superconducting circuits. The majority of circuits employed in various superconductor electronics applications are composed of closed loops of superconducting wire that can be interrupted by one or more Josephson junctions (e.g., a superconducting quantum interference device (SQUID)). While the Meissner effect precludes the trapping of magnetic flux lines within the interior of defect-free superconducting films, magnetic flux lines are readily trapped within such loops and SQUIDs. The cooling of a superconducting loop from above its superconducting critical temperature to below the superconducting critical temperature while enclosing magnetic flux can result in a persistent current that flows in the loop that is inversely proportional to the inductance of the loop and proportional to the amount of enclosed magnetic flux. Such a circulating current can degrade the performance of the circuit containing the loop. The circulating current can also degrade the performance of adjoining circuits that have a non-negligible inductive coupling.

### SUMMARY

A superconductor device with a composite material ground plane is disclosed. In one example, a superconductor device includes a plurality of superconductor layers and dielectric layers interleaved with the plurality of superconductor layers with moat regions that extend through the plurality of superconductor layers and the dielectric layers. The superconductor device further includes a composite material ground plane that is one of the superconductor layers of the plurality of superconductor layers. The composite ground plane comprises first regions formed of a first superconductor material, and second regions formed of a second superconductor material having a second superconducting critical temperature higher than a first superconducting critical temperature of the first superconductor material, such that at least one flux vortex caused by cryogenic cooling can be removed from the second region during cooling below the second critical temperature and above the first critical temperature to the first regions, and removed from the first regions to the moat regions upon cooling below the first critical temperature.

In another example, a superconductor device includes a plurality of superconductor layers and dielectric layers interleaved with the plurality of superconductor layers with moat regions that extend through the plurality of superconductor layers and the dielectric layers and a composite material ground plane that is one of the superconductor layers of the plurality of superconductor layers. The composite ground plane comprises first regions formed of a first superconductor material that surrounds each respective moat, and second regions outside the first regions, the second regions formed of a second material having a second superconducting critical temperature higher than a first superconducting critical temperature of the first superconductor material, such that at least one flux vortex caused by cryogenic cooling can be removed from the second region during cooling below the second critical temperature and above the first critical temperature to the first regions, and removed from the first regions to the moat regions upon cooling below the first critical temperature. The superconductor device further includes a superconductor circuitry that resides within one or more of the plurality of superconductor layers that are not ground plane layers.

### BRIEF DESCRIPTION OF DRAWINGS

It is emphasized that, in accordance with standard practice in the industry, various features are not drawn to scale. In fact, the dimensions of various features shown can be arbitrarily increased or reduced for clarity of discussion.

FIG. 1 is an example of a component diagram of a superconductor device.

FIG. 2 is an illustration of an example top plan view of a superconductor device with a ground plane layer for trapping a magnetic flux vortex.

FIG. 3 is an illustration of an example top plan view of a superconductor device with a composite material ground plane layer for trapping a magnetic flux vortex.

FIG. 4 is an illustration of an example top plan view of a superconductor device with a composite material ground plane layer for trapping a magnetic flux vortex.

FIG. 5 is an illustration of an example top plan view of a superconductor device with a composite material ground plane layer for trapping a magnetic flux vortex.

FIG. 6 is an illustration of an example top plan view of a superconductor device with a composite material ground plane layer for trapping a magnetic flux vortex.

### DETAILED DESCRIPTION

The present disclosure relates to a superconductor device with a composite material ground plane and accounts for contingencies for non-uniform variations in superconductor layers. In one example, a superconductor device includes a plurality of superconductor layers and dielectric layers interleaved with the plurality of superconductor layers with moat regions that extend through the plurality of superconductor layers and the dielectric layers. The superconductor device further includes a composite material ground plane that is one of the superconductor layers of the plurality of superconductor layers. The composite ground plane comprises first regions formed of a first superconductor material, and second regions formed of a second superconductor material having a second superconducting critical temperature higher than a first superconducting critical temperature of the first superconductor material, such that at least one flux vortex caused by cryogenic cooling can be removed from the second region during cooling below the second critical temperature and above the first critical temperature to the first regions, and removed from the first regions to the moat regions upon cooling below the first critical temperature.

Superconducting loops can enclose more than one flux vortex. The amount of magnetic flux vortices trapped in a given loop comprising a superconducting IC is difficult to predict and characterize and depends in part on the profile of the background magnetic field, rate of cooling, and the potential energy profile of the circuit which depends on the precise layout of the IC. Due to the impact on circuit performance of magnetic flux trapping and the difficulty in knowing a priori where the magnetic flux will tend to reside, superconducting IC designs routinely employ moat (e.g., opening) structures which are located in non-active parts of the circuit and which provide preferential magnetic flux trapping sites that will not degrade circuit performance. However, there are no contigencies for non-uniform variations in superconductor layers.

Having the second superconducting critical temperature of the second material set to be higher than the first superconducting critical temperature of the first superconductor material enables preferential magnetic flux trapping sites that are predictable and do not degrade circuit performance. Specifically, flux will move from the second regions formed of the second material to the first regions formed of the first material at the second superconducting critical temperature as the second regions begin to superconduct. Thereafter, the temperature of the superconductor device will continue to be cooled to a temperature between the second superconducting critical temperature and the first superconducting critical temperature.

According to one example where the first region does not have uniform widths, when this occurs, the flux will move from any narrower portions of the first region to the wider portions of the first region. Finally, when the temperature of the superconductor device reaches the first superconducting critical temperature or below, the flux will move from the first regions formed of the first material to the moat regions formed as the first regions begin to superconduct. It should be noted that the area of the second regions can be sized or selected to be certain areas based on Equations (1)-(5), discussed in greater detail below.

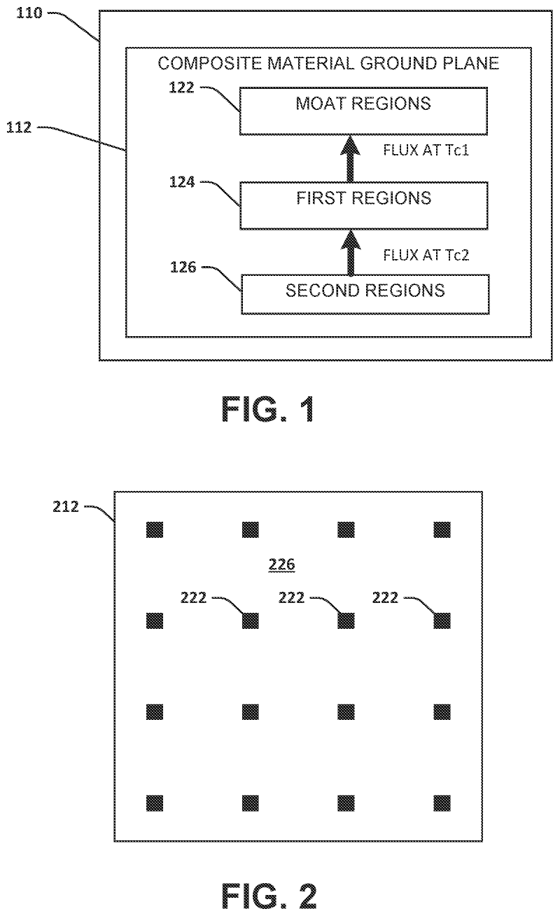

FIG. 1 is an example of a component diagram of a superconductor device 110. The superconductor device 110 can include a plurality of superconductor layers which can be interleaved with dielectric layers. A layer of the plurality of superconductor layers can be a composite material ground plane layer 112. The composite material ground plane layer 112 can include a plurality of moat regions 122, a plurality of first regions 124, and a plurality of second regions 126. As used herein, a moat region is a moat opening through the layers (e.g., the plurality of superconductor layers and the dielectric layers) of the superconductor device 110 with a superconductor material perimeter on the composite material ground plane layer 112 about the moat opening that can include a circulating current generated by the flux in the moat region 122 that facilitates the trapping of the flux in the moat opening.

The plurality of moat regions 122 can be configured to trap magnetic flux vortex as the superconductor layer is cooled to below a superconducting critical temperature T (or a series of superconducting critical temperatures T (1, Tc2, . . . for different regions within a multi-critical-temperature, composite material ground plane layer 112 comprising the plurality of first regions 124 and the plurality of second regions 126). The plurality of moat regions 122 can be arranged in a grid configuration or in an array configuration about the composite material ground plane layer 112.

The plurality of first regions 124 can be formed of a first superconductor material having a first superconducting critical temperature T_{c1}. The plurality of second regions 126 can be formed of a second superconductor material having a second superconducting critical temperature T_{c2} different than the first superconducting critical temperature. For example, the second superconducting critical temperature T_{c2} can be higher than or greater than the first superconducting critical temperature T_{c1}.

The reason for having the second superconducting critical temperature T_{c2} be higher than or greater than the first superconducting critical temperature T_{c1} is that this will cause at least one flux vortex caused by cryogenic cooling to be removed from the second region 126 during cooling below the second critical temperature T_{c2} and above the first critical temperature T_{c1} to the first regions 124, and removed from the first regions 124 to the moat regions 122 upon cooling below the first critical temperature T_{c1}. In order for this funneling effect to be achieved (i.e., have the flux be ‘pushed’ from the second regions 126 to the first regions 124 to the moat regions 122), each of the moat regions 122 can be surrounded by or substantially surrounded by the first regions 124. Stated another way, each given first region of the first regions 124 surround a given respective moat region for each of the moat regions 122. Similarly, each of the first regions 124 can be surrounded by, substantially surrounded by, or adjacent to one or more of the second regions 126.

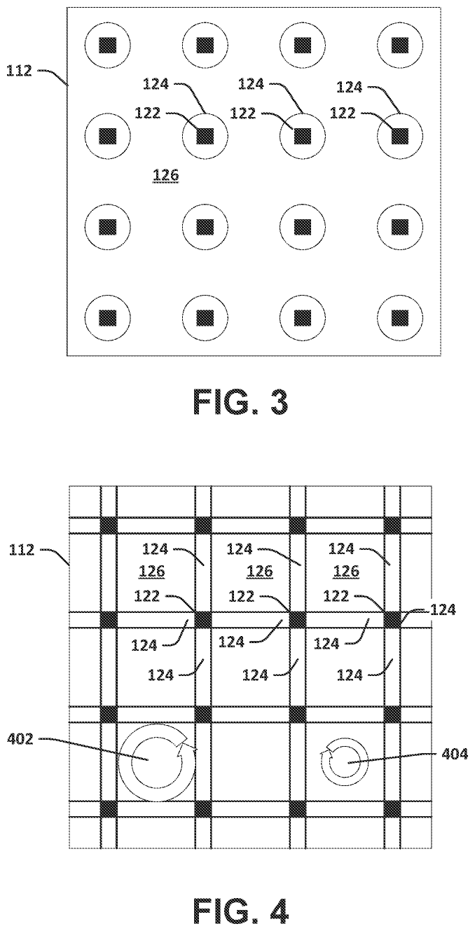

In this way, the plurality of first regions 124 and the plurality of second regions 126 can be utilized to form the composite material ground plane layer 112 in a manner to trap magnetic flux more efficiently and more precisely into the plurality of moat regions 122 during cooldown of the superconductor device 110 from the second critical temperature T_{c2} to the first critical temperature T_{c1} and below. Stated another way, the structure formed of the first material having the first superconducting critical temperature and the second superconducting critical temperature different than the first superconducting critical temperature and the arrangement of the materials in certain geometric patterns, as discussed below with reference to FIGS. 3-6, ensures that any residual magnetic field or flux that is present during cooldown of the chip will be confined to the plurality of moat regions 122.

Although the disclosure is described herein with reference to the first material having a lower (relative to the second material), first superconducting critical temperature of T_{c1}=9.0K and the second material having a higher (relative to the first material), second superconducting critical temperature of T_{c2}=9.3K, it will be appreciated that different materials and different first superconducting critical temperatures T_{c1} and second superconducting critical temperatures T_{c2} can be implemented. According to one example, the plurality of first regions 124 can be formed of a niobium alloy (e.g., a niobium-tantalum alloy) or an implanted or doped region and the plurality of second regions 126 can be formed of niobium. Again, other materials can be considered. Similarly, different geometric patterns can be formed using the plurality of moat regions 122, the plurality of first regions 124, and the plurality of second regions 126.

According to one example, the second superconducting critical temperature can be greater than the first superconducting critical temperature and there is no overlap in their transition temperatures. Due to this difference, during cooldown, the Meissner effect expels the magnetic field from the portions of the composite material ground plane layer 112 with the higher superconducting critical temperature (e.g., from the plurality of second regions 126) when the second superconducting critical temperature T_{c2} is reached. As seen in FIGS. 3-6, the plurality of moat regions 122 are adjacent to or substantially surrounded or encompassed by the plurality of first regions 124, which have lower superconducting critical temperatures than the plurality of second regions 126.

Since the plurality of first regions 124 have lower superconducting critical temperatures than the plurality of second regions 126, the plurality of first regions 124 condense superfluid current last during cooldown, or after the plurality of second regions 126 because their first superconducting critical temperature T_{c1} is reached after the second superconducting critical temperature T_{c2} is reached. This means that at the second superconducting critical temperature T_{c2}, the second regions 126 are starting to superconduct while the first regions 124 are not yet superconducting. Therefore, the first regions 124 act as moats when the second superconducting critical temperature T_{c2} is reached but the first superconducting critical temperature T_{c1} is not yet reached. In this way, the magnetic flux can first be pushed toward the plurality of first regions 124 from the plurality of second regions 126, then toward the plurality of moat regions 122 from the plurality of first regions 124. As cooling continues, the first superconducting critical temperature T_{c1} is reached. However, at this point, the flux has already exited the second regions 126 because the first regions 124 act as moats at the second superconducting critical temperature T_{c2}. Since the first regions 124 of FIGS. 3-6 are adjacent to the moat regions 122, this enables the flux to be funneled from the first regions 124 to the moat regions 122 when the first superconducting critical temperature T_{c1} is reached. That is, at the first superconducting critical temperature T_{c1}, the first regions 124 are starting to superconduct, which pushes the flux toward the moat regions 122. Since the superconducting of the composite material ground plane layer 112 occurs in stages (e.g., from the second superconducting critical temperature T_{c2} to the first superconducting critical temperature T_{c1}) the flux is pushed from the second regions 126 to the first regions 124 to the moat regions 122 in a successive manner, thereby mitigating any leftover or ‘trapped’ flux.

FIG. 2 is an illustration of an example top plan view of a superconductor device with a ground plane layer 212 for trapping a magnetic flux vortex. As seen in FIG. 2, a single material 226 has been previously used for ground plane design. The ground plane layer 212 can have a plurality of moat regions 222 arranged in a grid configuration or in an array configuration. The plurality of moat regions 222 can be void of material, for example. The plurality of moat regions 222 provide low energy trapping sites most ideally when the entire layer reaches a superconducting critical temperature (and thus, superconducting) at the same moment in time.

The plurality of moat regions 222 are a local minimum in the potential energy and magnetic flux is sequestered in the plurality of moat regions 222. However, non-uniformities as small as 20 millikelvin (mK) can create potential energy minima for stray magnetic flux to be trapped outside of the plurality of moat regions 222. In this scenario, a superconductor chip that operated correctly on a previous cooldown can fail to operate after a successive cooldown. This lack of repeatability is a problem in superconductive electronics.

The superconductor device 110 described herein can operate correctly on both the previous cooldown and the successive cooldown due to the plurality of first regions 124 having different superconducting critical temperatures than the plurality of second regions 126 and based on the geometric patterns formed by the plurality of first regions 124 and the plurality of second regions 126, thereby providing the advantage or benefit of repeatability cooldown performance.

FIG. 3 is an illustration of an example top plan view of a superconductor device with the composite material ground plane layer 112 for trapping a magnetic flux vortex. As seen in FIG. 3, each of the plurality of first regions 124 can substantially encompass each of the plurality of moat regions 122 and each of the given first regions 124 have a generally circular shape. Additionally, the plurality of second regions 126 can form a contiguous region that surrounds each of the first regions 124 and each of the moat regions 122. In the example of FIG. 3, a first geometric pattern is shown based on materials with distinct critical temperatures, which can enable effective trapping of magnetic flux in the plurality of moat regions 122, to enable highly repeatable performance of Josephson ICs. In this example, the plurality of moat regions 122 are located within the plurality of first regions 124 with the first superconducting critical temperature. When the main region (e.g., the plurality of second regions 126) of composite material ground plane layer 112 goes to superconducting (e.g., at 9.3 K or a second, higher superconducting critical temperature), the Meissner effect will expel the residual magnetic field and force the magnetic flux into the first regions 124 of first superconducting critical temperature (e.g., at 9.0 K or a first, lower superconducting critical temperature). When the chip is cooled below the first superconducting critical temperature, the magnetic flux is trapped in the plurality of moat regions 122, where the magnetic flux will not interfere with circuit functions.

According to one non-limiting example, the second material can have a second superconducting critical temperature that is 300 mK greater than the first material, which relaxes any requirement for superconducting critical temperature uniformity in the higher temperature superconductor. The composite material ground plane layer 112 can easily tolerate superconducting critical temperature variations as large as 250 mK, and still work correctly. Single-material ground planes, on the other hand, require superconducting critical temperature uniformity better than 20 mK to mitigate stray magnetic flux.

FIG. 4 is an illustration of an example top plan view of a superconductor device with the composite material ground plane layer 112 for trapping a magnetic flux vortex. In the example of FIG. 4, a second geometric pattern is shown where the plurality of moat regions 122, the plurality of first regions 124, and the plurality of second regions 126 are arranged according to a taxicab geometry or a Manhattan geometry. In this example, the city blocks (e.g., the plurality of second regions 126) are formed of a second material having a higher, second superconducting critical temperature, the streets and avenues (e.g., the plurality of first regions 124) are formed of a first superconducting critical temperature material, and the intersections are the plurality of moat regions 122, which can include holes or voids in the composite material ground plane layer 112.

Explained another way, the first regions 124 can be formed in rows and columns of conductive lines that connect moat regions 122 to one another into rows and columns of moat regions 122 in a grid arrangement, wherein the rows and columns of conductive lines separate the second regions 126 into plate regions, which can have a generally square shape, isolated from one another by the first regions 124. Furthermore, the plate regions or second regions 126 can be sized to have an area, such that circulating current of the Meissner effect dominates circulating current of the Abrikosov effect, as discussed in greater detail below.

The first areas or portions of the composite material ground plane layer 112 to go superconducting (T_{c2}=9.3K) in FIG. 4 are the plates of the second material (e.g., the plurality of second regions 126) having the higher, second superconducting critical temperature. According to one example, the plates of the second regions 126 can have dimensions of 10 μm×10 μm while the moat regions 122 can have dimensions of 2 μm×2 μm. When the chip is protected by mu-metal shields, the earth's magnetic field is screened by a factor 50×-1000×. The residual field at the chip is in the range 50-1000 nanoTesla. This low residual field can make it difficult to trap a stray flux in a plate.

Superconductivity is a diamagnetic effect. The Meissner effect favors counterclockwise currents that shield the plate (e.g., the plurality of second regions 126) from the residual field. The Meissner current 402 is the current which expels flux from the superconductor and is energetically favored over an Abrikosov current 404. A stray flux residing in the second regions 126 are an Abrikosov vortex of superfluid current, with a much larger clockwise circulating current than the Meissner current 402. The inductance of a 10 μm×10 μm plate (e.g., an example dimension for the second regions) of superconductor is approximately 20 pH. The Abrikosov current 404 is about 100 uA since L*I=Φ₀=2,000 pH*μA. By contrast, the Meissner current 402 is small by comparison. For a residual field as high as 2 μT, the diamagnetic Meissner current 402 is only 10 μA. Since the energy in an inductor increases as the square of the stored current, it takes one hundred times less energy to push the Meissner current 402 into the first superconducting critical temperature material, compared to a stray flux or Abrikosov current 404 in a plate or the second region, thereby making the Meissner current 402, the more favorable of the two currents.

In the configurations shown in FIGS. 4-6, the Meissner current 402 is the resultant lower energy state, which enables the plurality of moat regions 122 to trap the magnetic flux more easily than the Abrikosov current 404. For example, assuming T_{c1}=9.0K for the plurality of first regions 124 and T_{c2}=9.3K for the plurality of second regions 126, when the temperature reaches 9.1K (i.e., a temperature between T_{c1} and T_{c2}), the magnetic flux will reside in the plurality of first regions 124 and the plurality of moat regions 122, but not in the plurality of second regions 126 because the Meissner effect causes the plurality of second regions 126 to become magnetic flux exclusion zones while the plurality of first regions 124 are not superconductive, and thus act as moats until they reach superconductivity.

$${B}_{Agressor} = 2 μ T \qquad ( 1 )$$

$${I}_{Meissner} = \frac{B * {A}_{Plate}}{{L}_{Plate}} \qquad ( 2 )$$

$${I}_{Abrikosov} = \frac{{Φ}_{o}}{{L}_{Plate}} \qquad ( 3 )$$

$$E = \frac{{LI}^{2}}{2} \qquad ( 4 )$$

$$B * {A}_{Plate} = {Φ}_{o} @ 20 μ T \qquad ( 5 )$$

It is desired to have the circulating current of the Meissner effect be energetically lower than the circulating current of the Abrikosov effect, which results in a greater likelihood of the Meissner effect occurring. Thus, in order to achieve this, the plate regions or second regions 126 can be sized to have an area A_{Plate} such that the energy of I_{Meissner}<the energy of I_{Abrikosov} (i.e., E_{Meissner}<E_{Abrikosov}) since the supercurrent with the lowest energy state will generally occur. As seen above from Equation (4), the energy E in an inductor L increases as the square of the stored current I². Since I_{Meissner} is the preferred supercurrent, it is desirable to have the I_{Meissner}<I_{Abrikosov} to satisfy E_{Meissner}<E_{Abrikosov}. In greater detail, when I_{Meissner}<I_{Abrikosov}, then the I_{Meissner} will have a lower energy state than I_{Abrikosov}, thereby resulting in an occurrence of the Meissner current 402 and no occurrence of the Abrikosov current 404. As seen above from Equation (2), the Meissner current I_{Meissner} is equal to B multiplied by an area of the plate A_{Plate} (e.g., an area of one plate from the plurality of second regions) divided by an inductance of the plate L_{Plate} (e.g., an inductance of one plate from the plurality of second regions). As seen above from Equation (3), the Abrikosov current I_{Abrikosov} is equal to a magnetic flux quantum Φ₀ divided by the inductance of the plate L_{Plate} (e.g., the inductance of one plate from the plurality of second regions). Therefore, in order to design the superconductor device to achieve this occurrence of the Meissner current 402, B*A_{Plate} is selected to be less than Φ₀, because both the I_{Meissner} and I_{Abrikosov} are inversely proportional to L_{Plate}. One way of achieving this is to set the A_{Plate} (e.g., the area of the second region 126) such that B*A_{Plate}<Φ₀/2.

In FIGS. 4-6, each of the plurality of second regions 126 is substantially centered with respect to the four nearest moat regions of the plurality of moat regions 122. Additionally, each of the plurality of moat regions 122 is substantially centered with respect to the four nearest second regions of the plurality of second regions 126. Each of the plurality of second regions 126 can have a quadrilateral shape, a square shape, a square shape with rounded corners, a rounded shape, etc. Each of the plurality of moat regions 122 can have a quadrilateral shape, a square shape, a diamond shape, etc.

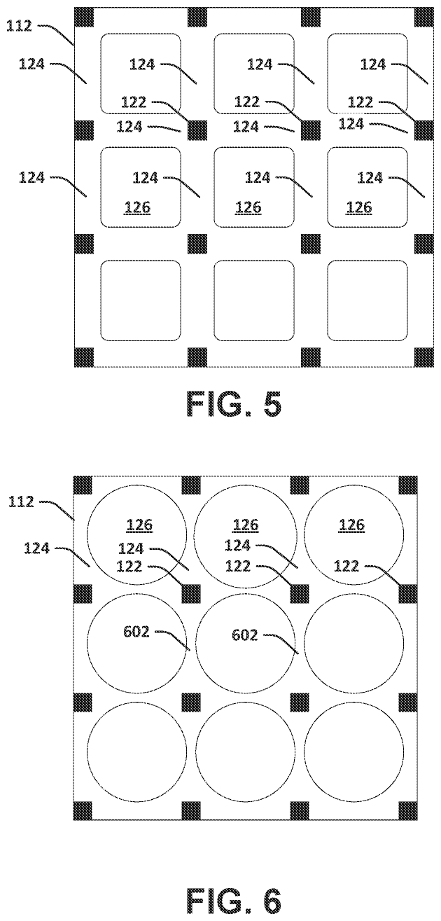

FIG. 5 is an illustration of an example top plan view of a superconductor device with the composite material ground plane layer 112 for trapping a magnetic flux vortex. According to one example, every moat is surrounded by the first superconducting critical temperature material. During cooldown, the residual magnetic field is pushed into the first superconducting critical temperature material when the chip temperature reaches 9.3 K. The second material does not need any large degree of uniformity in its critical temperature, since the residual flux is not confined as single flux quanta until the first superconducting critical temperature is reached at 9.0 K. In FIG. 5, the first regions 124 include generally intersection or street shaped areas surrounding the moat regions 122 that define the plate regions or the second regions 126 with a generally square shape with cutoff corners.

In FIGS. 5-6, the plurality of first regions 124 can form a contiguous region. The contiguous region of the plurality of first regions 124 can encompass the plurality of moat regions 122 arranged in a grid configuration or in an array configuration and the plurality of second regions 126 arranged in an alternating grid configuration or in an array configuration with respect to the plurality of moat regions 122.

FIG. 6 is an illustration of an example top plan view of a superconductor device with the composite material ground plane layer 112 for trapping a magnetic flux vortex. The example of FIG. 6 ensures that no Abrikosov vortex can form in the streets and avenues (e.g., the plurality of first regions 124) of the first superconducting critical temperature material because the plates or the second regions 126 are sized to make the I_{Meissner} dominate over I Abrikosov by designing E_{Meissner}<E_{Abrikosov}, as discussed above with reference to the area of the plate A_{Plate} or second region 126. In FIG. 6, the first regions 124 include generally diamond shape areas surrounding the moat regions 122 that define the plate regions or the second regions 126 to have a generally circular shape.

Thus, the first regions 124 have narrow portions 602 in the middle portion of adjoining sides of adjacent plate or second regions 126. The narrow portions 602 of the first regions 124 are the regions having the smallest separation between respective second regions 126, which facilitates movement of flux from the narrowest portion to wider regions that surround the moat regions 122. The reason for this is because the narrow portions 602 of the first regions 124 are the first portions of the first regions 124 to go superconducting during cooldown to temperatures approximate to the first superconducting critical temperature T_{c1} as a result of the proximity effect. Specifically, the proximity effect ensures that the first portions of the streets and avenues (e.g., the plurality of first regions 124) to go superconducting will be the narrower portions 602 or areas in the middle of the blocks, as shown in FIG. 6. The proximity effect can be used to initiate superconductivity in the middle of the streets and avenues (e.g., the plurality of first regions 124) of first superconducting critical temperature material, where the regions of higher superconducting critical temperature second material have the smallest separation at the narrower portions 602.

During cooldown from the second superconducting critical temperature T_{c2} to the first superconducting critical temperature T_{c1}, the phase transition progresses from the middle, narrowest portions 602 of the blocks toward the intersections, where the flux is sequestered in the plurality of moat regions 122. Initially, when the second superconducting critical temperature T_{c2} is reached, the superfluid current condenses the flux to the middle of the portions 602 or blocks, then progressively squeezes the residual magnetic field into a shrinking region of normal metal at the wider portions of the first regions 124, as a result of the proximity effect. The proximity effect raises the superconducting critical temperature of the narrowest portions 602 of the streets and avenues (e.g., the plurality of first regions 124), thereby causing the narrowest portions 602 of the first areas to superconduct prior to other, wider portions of the first regions 124. The advancing front of superconducting phase acts as a superfluid current ‘squeegee’ to push the magnetic flux into the plurality of moat regions 122, as desired.

The geometric arrangement of higher, second superconducting critical temperature (e.g., the plurality of second regions 126) and lower, first superconducting critical temperature (e.g., the plurality of first regions 124) of FIGS. 4-6 are similar to the geometric arrangement of a tortoise shell. The composite material ground plane layer 112 of the superconductor device 110 uses the higher, second superconducting critical temperature material for the plurality of second regions 126 to prevent entry of Abrikosov vortices into a unit cell. This is possible because the plates of the plurality of second regions 126 have a small area that will not intercept any significant fraction of a single flux quantum at practical magnetic fields. The first superconducting critical temperature material of the plurality of first regions 124 receives the magnetic flux that is diverted from the plates or the plurality of second regions 126 when the plates of the plurality of second regions 126 go superconducting. Finally, the first superconducting critical temperature material transitions to the superconducting state, beginning at their narrowest regions or the narrow portions 602. This final transition quantizes the magnetic flux. As the region of superconductivity grows, any flux is pushed into the plurality of moat regions 122, where there is no superconductive material.

The composite material ground plane layer 112 for trapping the magnetic flux vortex is very tolerant of local variations in critical temperature. The plates or the plurality of second regions 126 will exclude Abrikosov vortices if the entire plate goes superconductive before the surrounding first superconducting critical temperature material begins to transition. This is easier to achieve than demanding uniform critical temperature across the ground plane of the entire chip. In this way, the composite material ground plane layer 112 for trapping the magnetic flux uses a composite of materials to achieve perfect sequestering of magnetic flux in the plurality of moat regions 122.

What have been described above are examples of the invention. It is, of course, not possible to describe every conceivable combination of components or methodologies for purposes of describing the invention, but one of ordinary skill in the art will recognize that further combinations and permutations of the invention are possible. Accordingly, the invention is intended to embrace all such alterations, modifications, and variations that fall within the scope of this application, including the appended claims.

What is claimed is:

1. A superconductor device comprising:
a plurality of superconductor layers and dielectric layers interleaved with the plurality of superconductor layers with moat regions that extend through the plurality of superconductor layers and the dielectric layers; and
a composite material ground plane that is one of the superconductor layers of the plurality of superconductor layers, the composite ground plane comprises first regions formed of a first superconductor material, and second regions formed of a second superconductor material having a second superconducting critical temperature higher than a first superconducting critical temperature of the first superconductor material, such that at least one flux vortex caused by cryogenic cooling is removed from the second region during cooling below the second critical temperature and above the first critical temperature to the first regions, and removed from the first regions to the moat regions upon cooling below the first critical temperature.

2. The superconductor device of claim 1, wherein each given first region of the first regions surround a given respective moat region for each of the moat regions.

3. The superconductor device of claim 2, wherein each of the given first regions have a generally circular shape.

4. The superconductor device of claim 3, wherein the second regions form a contiguous region that surrounds each of the first regions and each of the moat regions.

5. The superconductor device of claim 1, wherein the moat regions are arranged in a grid configuration or in an array configuration about the composite material ground plane.

6. The superconductor device of claim 1, wherein the first regions are formed in rows and columns of conductive lines that connect moat regions to one another into rows and columns of moat regions in a grid arrangement, wherein the rows and columns of conductive lines separate the second regions into plate regions isolated from one another by the first regions.

7. The superconductor device of claim 6, wherein the plate regions are sized to have an area, such that circulating current of the Meissner effect dominates circulating current of the Abrikosov effect.

8. The superconductor device of claim 6, wherein the plate regions have a generally square shape.

9. The superconductor device of claim 8, wherein the first regions include generally diamond shape areas surrounding the moat regions that define the plate regions to have a generally square shape with cutoff corners.

10. The superconductor device of claim 6, wherein each of the plate regions have a generally round shape.

11. The superconductor device of claim 10, wherein the first regions have narrow portions in the middle portion of adjoining sides of adjacent plate regions that result in the smallest separation between second regions to facilitate movement of flux from the narrowest portion that go superconducting first during cooldown to wider regions that surround the moat regions.

12. A superconductor device comprising:
a plurality of superconductor layers and dielectric layers interleaved with the plurality of superconductor layers with moat regions that extend through the plurality of superconductor layers and the dielectric layers;
a composite material ground plane that is one of the superconductor layers of the plurality of superconductor layers, the composite ground plane comprises first regions formed of a first superconductor material that surrounds each respective moat, and second regions outside the first regions, the second regions formed of a second material having a second superconducting critical temperature higher than a first superconducting critical temperature of the first superconductor material, such that at least one flux vortex caused by cryogenic cooling is removed from the second region during cooling below the second critical temperature and above the first critical temperature to the first regions, and removed from the first regions to the moat regions upon cooling below the first critical temperature; and
superconductor circuitry that resides within one or more of the plurality of superconductor layers that are not ground plane layers.

13. The superconductor device of claim 12, wherein each of the given first regions have a generally circular shape.

14. The superconductor device of claim 13, wherein the second regions form a contiguous region that surrounds each of the first regions and each of the moat regions.

15. The superconductor device of claim 12, wherein the moat regions are arranged in a grid configuration or in an array configuration about the composite material ground plane.

16. The superconductor device of claim 12, wherein the first regions are formed in rows and columns of conductive lines that connect moat regions to one another into rows and columns of moat regions in a grid arrangement, wherein the rows and columns of conductive lines separate the second regions into plate regions isolated from one another by the first regions.

17. The superconductor device of claim 16, wherein the plate regions are sized to have an area, such that circulating current of the Meissner effect dominates circulating current of the Abrikosov effect.

18. The superconductor device of claim 16, wherein the plate regions have a generally square shape.

19. The superconductor device of claim 18, wherein the first regions include generally diamond shape areas surrounding the moat regions that define the plate regions to have a generally square shape with cutoff corners.

20. The superconductor device of claim 16, wherein the first regions have narrow portions in the middle portion of adjoining sides of adjacent plate regions that result in the smallest separation between second regions to facilitate movement of flux from the narrowest portion that go superconducting first during cooldown to wider regions that surround the moat regions.
